(19) United States
(12) Patent Application Publication
(10) Pub. No.: US 2025/0392331 A1
(43) Pub. Date: Dec. 25, 2025

(54) DIPLEXER-BASED PIEZOELECTRIC UNWANTED SPURS AND LOSSES REDUCTION TECHNIQUE

(71) Applicant: Qorvo US, Inc., Greensboro, NC (US)

(72) Inventor: Chris Levesque, Fountain Valley, CA (US)

(21) Appl. No.: 19/241,608

(22) Filed: Jun. 18, 2025

Related U.S. Application Data
(60) Provisional application No. 63/661,967, filed on Jun. 20, 2024.

(51) Int. Cl. H04B 1/00; H03H 9/54

(52) U.S. Cl. CPC H04B 1/0078; H03H 9/545

(57) ABSTRACT

Radio frequency (RF) circuits and method of operating the same are disclosed. In some embodiments, the RF circuit includes an input terminal and an output terminal. A first filter path is connected between the input terminal and the output terminal the first filter path including an piezoelectric filter, a first filter and a second filter, wherein the piezoelectric filter is connected between the first filter and the second filter. The second filter path is connected between the input terminal and the output filter, wherein the second filter path includes a third filter and a fourth filter, wherein both the third filter and the fourth filter are of a second type of filter. The first type of filter is one of either a low pass a high pass type filter. The second type of filter is of another one of the low pass the high pass type filter.

### RELATED APPLICATIONS

This application claims the benefit of provisional patent application Ser. No. 63/661,967, filed Jun. 20, 2024, the disclosure of which is hereby incorporated herein by reference in its entirety.

### FIELD OF THE DISCLOSURE

This disclosure relates generally to radio frequency (RF) filters that utilize piezoelectric filters, and methods of operating the same.

### BACKGROUND

Piezoelectric filters are utilized in front-end radio frequency (RF) modules to isolate desired signals while rejecting unwanted interference, noise, and adjacent channel signals. Utilizing the piezoelectric effect, piezoelectric filters can precisely manipulate piezoelectric waves to achieve high selectivity and low insertion losses, thereby maximizing key metrics for optimizing signal quality. Whether it's in cellular networks, Wi-Fi, or Bluetooth connections, piezoelectric filters help ensure reliable and efficient communication by maintaining signal integrity and minimizing interference, ultimately enhancing the overall performance of RF modules in modern wireless devices.

Piezoelectric filters can be utilized to provide notches in the frequency spectrum. Piezoelectric filters that have a notch are designed to deliver precise rejection capabilities, attenuating a specific value in decibels across a defined frequency spectrum. The frequencies that fall outside the notch's frequency range remain unaffected, ensuring minimal signal loss. The sharpness of the notch is a critical feature, necessitating a high Q factor, which is a hallmark of piezoelectric technologies. Despite their advantages, piezoelectric technologies are not without their drawbacks, as they can produce undesirable spurious responses and inherent bulk losses, particularly around the resonant frequencies. These unwanted anomalies can lead to significant amplitude fluctuations and increased insertion losses within the passbands.

### SUMMARY

In some embodiments, a radio frequency (RF) circuit includes: an input terminal; an output terminal; a first filter path connected between the input terminal and the output terminal, wherein the first filter path includes an piezoelectric filter, a first filter, and a second filter, wherein the piezoelectric filter is connected between the first filter and the second filter, wherein both the first filter and the second filter are of a first type of filter; a second filter path connected between the input terminal and the output terminal, wherein the second filter path includes a third filter and a fourth filter, wherein both the third filter and the fourth filter are of a second type of filter; wherein the first type of filter is one of either a low pass type filter or a high pass type filter; and wherein the second type of filter is of another one of the low pass type filter or the high pass type filter. In some embodiments, the first filter, the piezoelectric filter, and the second filter are cascaded in the first filter path; and the third filter and the fourth filter are connected sequentially in the second filter path, wherein another piezoelectric filter is not included in the second filter path. In some embodiments, the first type of filter is the low pass type filter and the second type of filter is the high pass type filter such that the first filter is a first low pass filter, the second filter is a second low pass filter, the third filter is a first high pass filter, and the fourth filter is a second high pass filter. In some embodiments, the piezoelectric filter defines an upper passband, a lower passband, and a notch between the upper passband and the lower passband; the upper passband defines a lower band edge; the first low pass filter and the second low pass filter each have a low pass corner frequency that is at or is above a high notch edge of the notch; and the first high pass filter and the second high pass filter each have a high pass corner frequency that is at or is above the high notch edge of the notch. In some embodiments, the upper passband defines an upper band edge that is higher than the lower band edge of the upper passband; the piezoelectric filter is configured to generate spurious modes above the lower band edge but below the upper band edge that degrade a section of the upper passband; the low pass corner frequency of both the first low pass filter and the second low pass filter is below the section of the upper passband to filter out the spurious modes from the first filter path; and the high pass corner frequency of both the first high pass filter and the second high pass filter is below the section of the upper passband to pass an RF signal in the section of the upper passband. In some embodiments, the first type of filter is the high pass type filter and the second type of filter is the low pass type filter such that the first filter is a first high pass filter, the second filter is a second high pass filter, the third filter is a first low pass filter, and the fourth filter is a second low pass filter. In some embodiments, the piezoelectric filter defines a lower passband, an upper passband, and a notch between the lower passband and the upper passband; the lower passband defines an upper band edge; the first high pass filter and the second high pass filter each have a high pass corner frequency that is at or is above the upper band edge of the lower passband; and the first low pass filter and the second low pass filter each have a low pass corner frequency that is at or is above the upper band edge of the lower passband. In some embodiments, the lower passband defines a lower band edge that is lower than the upper band edge; the piezoelectric filter is configured to generate spurious modes below the upper band edge but above the lower band edge that degrade a section of the lower passband; the high pass corner frequency of both the first high pass filter and the second high pass filter is above the section of the lower passband to filter out the spurious modes from the first filter path; and the low pass corner frequency of both the first low pass filter and the second low pass filter is above the section of the lower passband to pass an RF signal in the section of the lower passband. In some embodiments, the piezoelectric filter is an acoustic filter. In some embodiments, the piezoelectric filter is a surface acoustic wave (SAW) filter or a bulk acoustic wave (BAW) filter. In some embodiments, the RF circuit is formed in an integrated circuit (IC) package.

In some embodiments, a method of filtering an RF signal, includes: receiving the RF signal at an input terminal; splitting the RF signal so that a first split RF signal is transmitted through a first filter path and a second split RF signal is transmitted through a second filter path; filtering the first split RF signal with a first filter, a second filter, and an piezoelectric filter, wherein the piezoelectric filter is between the first filter and the second filter and wherein the first filter and the second filter are both of a first type of filter; filtering the second split RF signal with a third filter and a fourth filter in the second filter path, the third filter and the fourth filter are both of a second type of filter; recombining the first split RF signal and the second split RF signal into a recombined RF signal; wherein the first type of filter is one of either a low pass type filter or a high pass type filter; and wherein the second type of filter is of another one of the low pass type filter or the high pass type filter.

In some embodiments, a user element includes an RF circuit, the RF circuit includes: an input terminal; a first output terminal; a first filter path connected between the input terminal and the first output terminal, the first filter path including an piezoelectric filter, a first filter, and a second filter, wherein the piezoelectric filter is connected between the first filter and the second filter, wherein both the first filter and the second filter are of a first type of filter; a second filter path connected between the input terminal and the first output terminal, wherein the second filter path includes a third filter and a fourth filter, wherein both the third filter and the fourth filter are of a second type of filter; wherein the first type of filter is one of either a low pass type filter or a high pass type filter; and wherein the second type of filter is of another one of the low pass type filter or the high pass type filter. In some embodiments, the first filter, the piezoelectric filter, and the second filter are cascaded in the first filter path; and the third filter and the fourth filter are connected sequentially in the second filter path, wherein another piezoelectric filter is not included in the second filter path. In some embodiments, the first type of filter is the low pass type filter and the second type of filter is the high pass type filter such that the first filter is a first low pass filter, the second filter is a second low pass filter, the third filter is a first high pass filter, and the fourth filter is a second high pass filter. In some embodiments, the piezoelectric filter defines an upper passband, a lower passband, and a notch between the upper passband and the lower passband; the upper passband defines a lower band edge; the first low pass filter and the second low pass filter each have a low pass corner frequency that is at or is above the lower band edge of the upper passband; and the first high pass filter and the second high pass filter each have a high pass corner frequency that is at or is above the lower band edge of the upper passband. In some embodiments, the upper passband defines an upper band edge that is higher than the lower band edge; the piezoelectric filter is configured to generate spurious modes above the lower band edge but below the upper band edge that degrade a section of the upper passband; the low pass corner frequency of both the first low pass filter and the second low pass filter is below the section of the upper passband to filter out the spurious modes from the first filter path; and the high pass corner frequency of both the first high pass filter and the second high pass filter is below the section of the upper passband to pass an RF signal in the section of the upper passband. In some embodiments, the first type of filter is the high pass type filter and the second type of filter is the low pass type filter such that the first filter is a first high pass filter, the second filter is a second high pass filter, the third filter is a first low pass filter, and the fourth filter is a second low pass filter. In some embodiments, the piezoelectric filter defines a lower passband, an upper passband, and a notch between the lower passband and the upper passband; the lower passband defines an upper band edge; the first high pass filter and the second high pass filter each have a high pass corner frequency that is at or is below the upper band edge of the lower passband; and the first low pass filter and the second low pass filter each have a low pass corner frequency that is at or is below the upper band edge of the lower passband. In some embodiments, the lower passband defines a lower band edge that is lower than the upper band edge; the piezoelectric filter is configured to generate spurious modes below the upper band edge but above the lower band edge that degrade a section of the lower passband; the high pass corner frequency of both the first high pass filter and the second high pass filter is above the section of the lower passband to filter out the spurious modes from the first filter path; and the low pass corner frequency of both the first low pass filter and the second low pass filter is above the section of the lower passband to pass an RF signal in the section of the lower passband. In some embodiments, the piezoelectric filter is a SAW filter or a BAW filter.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a radio frequency (RF) circuit, in accordance with some embodiments;

FIG. 2 illustrates a frequency response of an piezoelectric filter shown in FIG. 1 when no other components are provided, in accordance with some embodiments;

FIG. 3 illustrates a frequency response of the RF circuit shown in FIG. 1, in accordance with some embodiments;

FIG. 4 illustrates another RF circuit, in accordance with some embodiments;

FIG. 5 illustrates a frequency response of an piezoelectric filter shown in FIG. 4 when no other components are provided, in accordance with some embodiments;

FIG. 6 illustrates a frequency response of the RF circuit shown in FIG. 4, in accordance with some embodiments;

FIG. 7 illustrates a flow diagram describing a method for filtering an RF signal, in accordance with some embodiments; and

FIG. 8 illustrates a user element, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying embodiments.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

Radio frequency (RF) circuits are disclosed. The RF circuits include two RF filter paths. In one RF filter path, an piezoelectric filter is provided between two filters while the other filter path is a bypass path. The piezoelectric filter is configured to provide a notch between a lower passband and an upper passband. The filters in this RF filter path are configured to filter out spurious modes in a section of either one of the passbands. For example, if a section of the upper passband is degraded by spurious modes of the piezoelectric filter, the piezoelectric filter is provided between two low pass filters. A low pass corner frequency of the two low pass filters is provided below the section of the upper passband and, thereby, filters out the spurious modes generated by the piezoelectric filter. In contrast, if a section of the lower passband is degraded by spurious modes of the piezoelectric filter, the piezoelectric filter is provided between two high pass filters. A high pass corner frequency of the high pass filters is provided above the section of the upper passband and, thereby, filters out the spurious modes generated by the piezoelectric filter.

If the two low pass filters are provided in the filter path with the piezoelectric filters, the two high pass filters are provided in the bypass path. The high pass corner frequency of the high pass filters is also below the section of the upper passband that would be degraded by spurious modes. In this manner, portions of an RF signal that are aligned with the section of the upper passband flow through the bypass path. In contrast, if the two high pass filters are provided in the filter path with the piezoelectric filters, the two low pass filters are provided in the bypass path. The low pass corner frequency of the low pass filters is also above the section of the lower passband that would be degraded by spurious modes. In this manner, portions of the RF signal that are aligned with the section of the lower passband flow through the bypass path. This arrangement allows for spurious modes caused by the piezoelectric filter to be removed while still allowing portions of the RF signal that would be affected by the spurious modes to pass through the output.

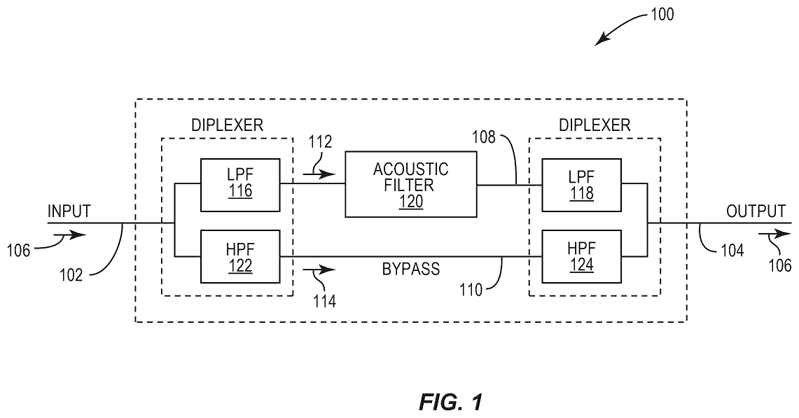

FIG. 1 illustrates an RF circuit 100, in accordance with some embodiments.

The RF circuit 100 shown in FIG. 1 is an RF filter. The RF circuit 100 is provided in a circuit package. The RF circuit 100 includes an input terminal 102 and an output terminal 104. An RF signal 106 is received by the RF circuit 100 at the input terminal 102 from external upstream circuitry (not explicitly shown). The RF signal 106 is then filtered by the RF circuit 100 and output at the output terminal 104 into external downstream circuitry (not explicitly shown). In some embodiments, the RF circuit 100 operates as a diplexer that allows for simultaneous reception and transmission of the RF signals 106. Thus, in some embodiments, the input terminal 102 also operates as an output terminal and the output terminal 104 also operates as an input terminal. More specifically, in some embodiments, an RF signal (such as the RF signal 106) is received at the output terminal 104, filtered by the RF circuit 100, and output at the input terminal 102.

The RF circuit 100 operates as a notch filter that provides a notch designed to deliver precise rejection capabilities, attenuating a specific frequency or a narrow specific frequency range in the frequency spectrum. The frequencies that fall outside of the frequency range of the notch are unaffected, ensuring minimal signal loss. The sharpness of the notch is important and the RF circuit 100 is designed to provide a high Q factor.

The RF circuit 100 includes an RF filter path 108 and an RF filter path 110. The RF filter path 108 is connected between the input terminal 102 and the output terminal 104. Similarly, the RF filter path 110 is connected between the input terminal 102 and the output terminal 104. In other words, there is a split between the input terminal 102 and the output terminal 104 of an RF filter path into the RF filter path 108 and the RF filter path 110. At the input terminal 102, the RF signal 106 is split into an RF signal 112 and an RF signal 114. The RF signal 112 propagates through the RF filter path 108 while the RF signal 114 propagates through the RF filter path 110.

To provide a notch, the RF circuit 100 utilizes a piezoelectric filter 120. As will explained in further detail below, the piezoelectric filter 120 is configured to provide an upper passband, a lower passband, and the notch between the upper passband and the lower passband. The piezoelectric filter 120 is a type of filter that utilizes piezoelectric waves to manipulate RF signals 106. The piezoelectric filter 120 is configured to provide the notch in order to reject specific frequencies within an RF frequency spectrum. The piezoelectric filter 120 converts an RF signal into mechanical vibrations (i.e., piezoelectric waves) within a piezoelectric material such as quartz or lithium niobate. These mechanical vibrations propagate through the material and interact with the RF signal, causing frequency-dependent phase shifts or amplitude changes. Various characteristics of the piezoelectric filter 120 selectively attenuate certain frequencies to provide the notch. The mechanical vibrations are then converted back into the filtered RF signal. The piezoelectric filter 120 is not without its drawbacks, as they can produce undesirable spurious responses and inherent bulk losses, particularly around the resonant frequencies. These unwanted anomalies can lead to significant amplitude fluctuations and increased insertion losses within the passbands. In some embodiments, the piezoelectric filter 120 is an acoustic filter. In some embodiments, the piezoelectric filter 120 is a bulk acoustic wave (BAW) filter and/or a surface acoustic wave (SAW) filter. In some embodiments, the piezoelectric filter 120 is temperature compensated.

With respect to the RF filter path 108, the RF filter path 108 includes a low pass filter (LPF) 116 and a low pass filter (LPF) 118. The piezoelectric filter 120 is connected between the low pass filter 116 and the low pass filter 118. The low pass filter 116, the piezoelectric filter 120, and the low pass filter 118 are connected in cascade. Accordingly, the RF signal 112 is filtered by the low pass filter 116, the piezoelectric filter 120, and the low pass filter 118.

With respect to the RF filter path 110, the RF filter path 110 includes a high pass filter (HPF) 122 and a high pass filter (HPF) 124. The high pass filter 122 and the high pass filter 124 are connected in cascade. Accordingly, the RF signal 114 is filtered by the high pass filter 122 and the high pass filter 124. After filtering, the RF signal 112 and the RF signal 114 are recombined at the output terminal 104 as the RF signal 106. The filtered RF signal 106 is then transmitted externally.

To correct for the spurious modes, the piezoelectric filter 120 is provided in the RF circuit 100. The RF circuit 100 provides the piezoelectric filter 120 in the RF filter path 108, where the spurious responses caused by the piezoelectric filter 120 are filtered out by the low pass filters 116, 118. The low pass filter 116 is provided for the input terminal 102 and the low pass filter 118 is provided for the output terminal 104. The RF filter path 110 serves as a bypass path that allows portions of the RF signal 106 that are in the frequency ranges of the spurious responses to pass to the output terminal 104. The high pass filters 122, 124 each define a corner frequency that allows the portions of the RF signal 106 that are in the frequency ranges of the spurious responses to pass to the output terminal 104. The high pass filter 122 is provided for the input terminal 102 and the high pass filter 124 is provided for the output terminal 104.

Filter topologies of the low pass filters 116, 118 and the high pass filters 122, 124 may be Butterworth, Chebyshev, inverse Chebyshev, Cauer (elliptic), or the like.

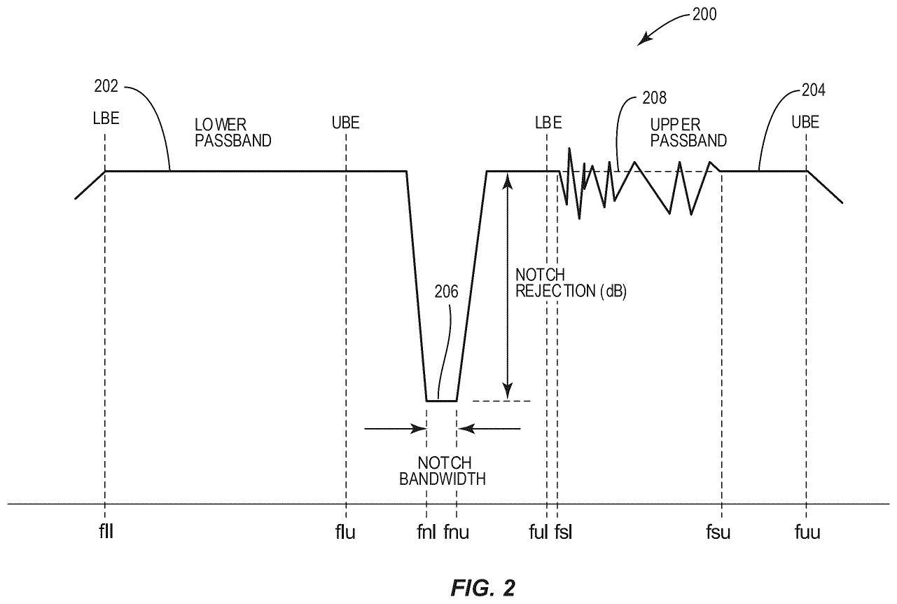

FIG. 2 illustrates a frequency response 200 of the piezoelectric filter 120 of FIG. 1 when no other components are provided, in accordance with some embodiments.

The piezoelectric filter 120 is configured to provide a lower passband 202, an upper passband 204, and a notch 206 between the upper passband 204 and the lower passband 202. The lower passband 202 is configured to pass frequencies between a lower band edge (LBE) at a frequency fll and an upper band edge (UBE) at a frequency flu. The notch 206 is configured to reject frequencies between a lower notch edge at a frequency fnl and an upper notch edge at a frequency fnu. The upper passband 204 is configured to pass frequencies between a lower band edge frequency at a frequency ful and an upper band edge at frequency fuu. However, the piezoelectric filter 120 is configured to generate spurious modes above the lower band edge frequency ful and below the lower band edge that degrades a section 208 of the upper passband 204. The section 208 between the lower band edge frequency ful and the upper band edge frequency fuu of the upper passband 204 is distorted. In this example, the section 208 of the upper passband 204 that is distorted by spurious modes is provided between a lower band edge frequency fsl and an upper band edge frequency fsu. The RF circuit 100 shown in FIG. 1 is configured to remove the spurious modes caused by the piezoelectric filter 120 and thereby pass portions of the RF signal 106 that are in the section 208 now with reduced distortion.

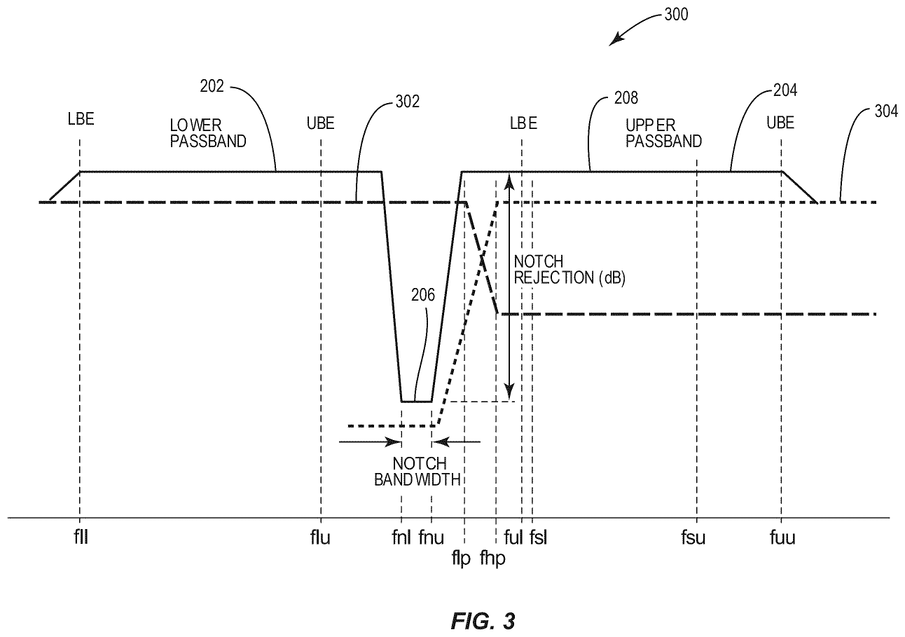

FIG. 3 illustrates a frequency response 300 of the RF circuit 100 shown in FIG. 1, in accordance with some embodiments.

The frequency response 300 has the lower passband 202, the upper passband 204 and the notch 206 as described above with respect to FIG. 2. However, as shown here in FIG. 3, the section 208 as shown in FIG. 2 is not distorted by the spurious modes of the piezoelectric filter 120.

Referring now to FIG. 1 and FIG. 3, each of the low pass filters 116, 118 in the RF filter path 108 have a same low pass frequency response 302. It should be noted that, in different embodiments, the low pass frequency response 302 of each of the low pass filters 116, 118 may not be exactly the same and be somewhat misaligned. In this embodiment, the low pass frequency response 302 of each of the low pass filters 116, 118 has a low pass corner frequency flp that is at or above the upper notch edge at the frequency fnu of the notch 206. More specifically, the low pass corner frequency flp is also below the lower band edge at the frequency fsl of the section 208. In this manner, the low pass frequency response 302 of the low pass filters 116, 118 filter out the spurious modes generated by the piezoelectric filter 120. Also, the section 208 of the upper passband 204 is not degraded. Thus, the portion of the RF signal 106 that is below the low pass corner frequency flp is passed as the split RF signal 112 and is filtered by the notch 206 of the piezoelectric filter 120. The notch 206 of the piezoelectric filter 120 filters the split RF signal 112. In this case, the rejection of the low pass filters 116, 118 in the upper passband 204 has to be sufficient to properly attenuate unwanted spurious and bulk losses. Depending on the severity, 10 to 20 dB of rejection for each of the low pass filters 116, 118 is adequate. Additionally, since the insertion loss of the lower passband 202 will be the sum of the two low pass filters 116, 118 and the piezoelectric filter 120, low loss elements may be used to fabricate the low pass filters 116, 118.

In this embodiment, each of the high pass filters 122, 124 in the RF filter path 110 have the same high pass frequency response 304. It should be noted that, in different embodiments, the high pass frequency response 304 of each of the high pass filters 122, 124 may not be exactly the same and be somewhat misaligned. In this embodiment, the high pass frequency response 304 of each of the high pass filters 122, 124 has a high pass corner frequency fhp that is at or above the upper notch edge at the frequency fnu of the notch 206. More specifically, the high pass corner frequency fhp is also below the lower band edge at the frequency fsl of the section 208. In this manner, the high pass frequency response 304 of the high pass filters 122, 124 pass portions of the RF signal 106 that are aligned with the section 208 of the upper passband 204. More specifically, the portion of the RF signal 106 that is above the high pass corner frequency fhp is passed as the split RF signal 114. In this manner, the low pass filters 116, 118 reject the spurious modes and bulk losses that would degrade the section 208, but the portion of the RF signal 106 that is aligned by the section 208 in the upper passband 204 is passed through the RF filter path 110. For the high pass filters 122, 124, the high pass corner frequency fhp is also above the upper notch edge at the frequency fnu and the rejection of the high pass filters 122, 124 at the upper notch edge at the frequency fnu is greater than the rejection of the notch 206. The exact amount of rejection of the high pass filters 122, 124 depends on many factors, including production margins, component tolerances, piezoelectric variations, and temperature.

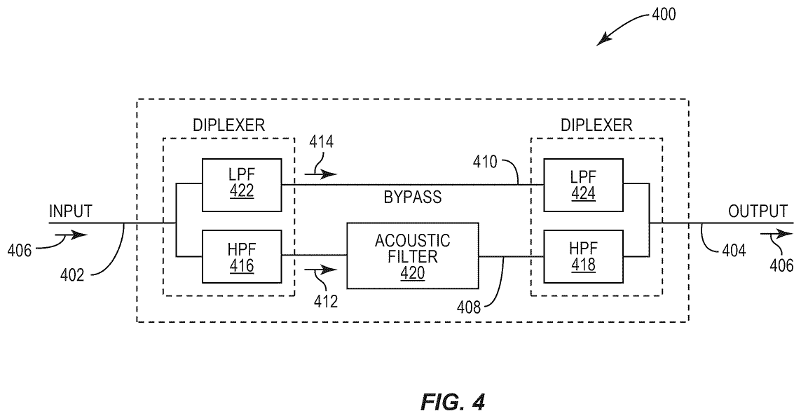

FIG. 4 illustrates an RF circuit 400, in accordance with some embodiments.

The RF circuit 400 shown in FIG. 4 is an RF filter. The RF circuit 400 is provided in a circuit package. The RF circuit 400 includes an input terminal 402 and an output terminal 404. An RF signal 406 is received by the RF circuit 400 at the input terminal 402 from external lowstream circuitry (not explicitly shown), filtered by the RF circuit 400, and output at the output terminal 404 to external downstream circuitry (not explicitly shown). In some embodiments, the RF circuit 400 operates as a diplexer that allows for simultaneous reception and transmission of RF signals 406. Thus, in some embodiments, the input terminal 402 also operates as an output terminal and the output terminal 404 also operates as an input terminal. More specifically, in some embodiments, an RF signal (such as the RF signal 406) is received at the output terminal 404, filtered by the RF circuit 400, and output at the input terminal 402.

The RF circuit 400 operates as a notch filter that provides a notch designed to deliver precise rejection capabilities, attenuating a specific frequency or a narrow specific frequency range in the frequency spectrum. The frequencies that fall outside the frequency range of the notch are unaffected, ensuring minimal signal loss. The sharpness of the notch is important and the RF circuit 400 is designed to provide a high Q factor.

The RF circuit 400 includes an RF filter path 408 and an RF filter path 410. The RF filter path 408 is connected between the input terminal 402 and the output terminal 404. Similarly, the RF filter path 410 is connected between the input terminal 402 and the output terminal 404. In other words, there is a split between the input terminal 402 and the output terminal 404 of an RF filter path into the RF filter path 408 and the RF filter path 410. At the input terminal 402, the RF signal 406 is split into an RF signal 412 and an RF signal 414. The RF signal 412 propagates through the RF filter path 408 while the RF signal 414 propagates through the RF filter path 410.

To provide a notch, the RF circuit 400 utilizes the piezoelectric filter 420. As will explained in further detail below, the piezoelectric filter 420 is configured to provide a lower passband, an upper passband, and the notch between the lower passband and the upper passband. The piezoelectric filter 420 is a type of filter that utilizes piezoelectric waves, typically in piezoelectric materials, to manipulate RF signals. The piezoelectric filter 420 is configured to provide the notch in order to reject specific frequencies within the RF frequency spectrum. The piezoelectric filter 420 converts an RF signal into mechanical vibrations (i.e., piezoelectric waves) within a piezoelectric material such as quartz or lithium niobate. These mechanical vibrations propagate through the material and interact with the RF signal, causing frequency-dependent phase shifts or amplitude changes. Various characteristics of the piezoelectric filter 420 selectively attenuate certain frequencies to provide the notch. The mechanical vibrations are then converted back into the filtered RF signal. The piezoelectric filter 420 is not without its drawbacks, as they can produce undesirable spurious responses and inherent bulk losses, particularly around the resonant frequencies. These unwanted anomalies can lead to significant amplitude fluctuations and increased insertion losses within the passbands. In some embodiments, the piezoelectric filter 420 is an acoustic filter. In some embodiments, the piezoelectric filter 420 is a BAW filter and/or a SAW filter. In some embodiments, the piezoelectric filter 420 is temperature compensated.

With respect to the RF filter path 408, the RF filter path 408 includes a high pass filter 416, a high pass filter 418, and the piezoelectric filter 420 connected between the high pass filter 416 and the high pass filter 418. The high pass filter 416, the piezoelectric filter 420, and the high pass filter 418 are connected in cascade. Accordingly, the split RF signal 412 is filtered by the high pass filter 416, the piezoelectric filter 420, and the high pass filter 418.

With respect to the RF filter path 410, the RF filter path 410 includes a low pass filter 422 and a low pass filter 424. The low pass filter 422 and the low pass filter 424 are coupled in cascade. Accordingly, the split RF signal 414 is filtered by the low pass filter 422 and the low pass filter 424. After filtering, the split RF signal 412 and the split RF signal 414 are recombined at the output terminal 404 as the filtered RF signal 406. The filtered RF signal 406 is then transmitted externally.

To correct for the spurious modes, the piezoelectric filter 420 is provided in the RF circuit 400. The RF circuit 400 provides the piezoelectric filter 420 in the RF filter path 408, where the spurious responses caused by the piezoelectric filter 420 are filtered out by the high pass filters 416, 418. The high pass filter 416 is provided for the input terminal 402 and the high pass filter 418 is provided for the output terminal 404. The RF filter path 410 serves as a bypass path that allows portions of the RF signal 406 that are in the frequency ranges of the spurious responses to pass to the output terminal 404. The low pass filters 422, 424 each define a corner frequency that allows the portions of the RF signal 406 that are in the frequency ranges of the spurious responses to pass to the output terminal 404. The low pass filter 422 is provided for the input terminal 402 and the low pass filter 424 is provided for the output terminal 404.

Filter topologies of the low pass filters 422, 424 and the high pass filters 416, 418 may be Butterworth, Chebyshev, inverse Chebyshev, Cauer (elliptic), or the like.

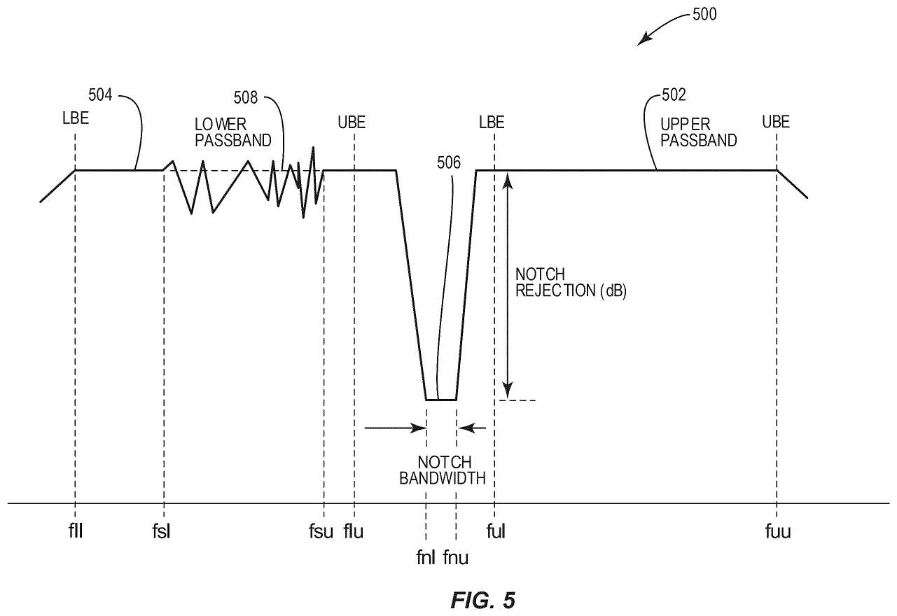

FIG. 5 illustrates a frequency response 500 of the piezoelectric filter 420 of FIG. 4 when no other components are provided, in accordance with some embodiments.

The piezoelectric filter 420 is configured to provide an upper passband 502, a lower passband 504, and a notch 506 between the lower passband 504 and the upper passband 502. The upper passband 502 is configured to pass frequencies between an upper band edge (UBE) at a frequency fuu and a lower band edge (LBE) at a frequency ful. The notch 506 is configured to reject frequencies between an upper notch edge at a frequency fnu and a lower notch edge at a frequency fnl. The lower passband 504 is configured to pass frequencies between an upper band edge at a frequency flu and a lower band edge at a frequency fll. However, the piezoelectric filter 420 is configured to generate spurious modes above the lower band edge at the frequency fll but below the upper band edge at the frequency flu that degrade a section 508 of the lower passband 504. The section 508 is between the upper band edge at the frequency flu and the lower band edge at the frequency fll of the lower passband 504. The section 508 is distorted. In this example, the section 508 of the lower passband 504 that is distorted by the spurious modes is provided between a higher frequency of fsu and a lower frequency of fsl. The RF circuit 400 as shown in FIG. 4 is configured to remove the spurious modes caused by the piezoelectric filter 420 and, thereby, pass portions of the RF signal 406 that are in the section 508 with or without reduced distortion.

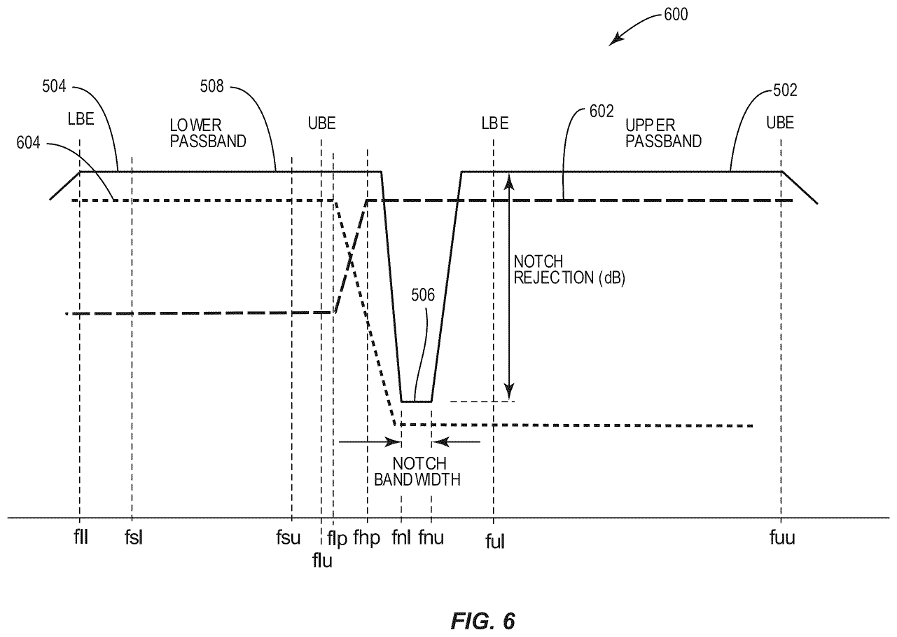

FIG. 6 illustrates a frequency response 600 of the RF circuit 400 shown in FIG. 4, in accordance with some embodiments.

The frequency response 600 has the upper passband 502, the lower passband 504, and the notch 506 as described above with respect to FIG. 5. However, as shown in FIG. 6, the section 508 of FIG. 5 is not distorted by the spurious modes of the piezoelectric filter 420.

Referring now to FIG. 4 and FIG. 6, each of the high pass filters 416, 418 in the RF filter path 408 have the same high pass frequency response 602. It should be noted that, in different embodiments, the high pass frequency response 602 of each of the high pass filters 416, 418 may not be exactly the same and may be somewhat misaligned. In this embodiment, the high pass frequency response 602 of each of the high pass filters 416, 418 has a high pass corner frequency fhp that is at or below the lower notch edge at the frequency fnl of the notch 506. More specifically, the high pass corner frequency fhp is also above the higher frequency fsu of the section 508. In this manner, the high pass frequency response 602 of the high pass filters 416, 418 filter out the spurious modes generated by the piezoelectric filter 420. Also, the section 508 of the lower passband 504 is not degraded. Thus, the portion of the RF signal 406 that is below the high pass corner frequency fhp is passed as the split RF signal 412 and is filtered by the notch 506 of the piezoelectric filter 420. The notch 506 of the piezoelectric filter 420 filters the split RF signal 412. In this case, the rejection of the high pass filters 416, 418 in the lower passband 504 has to be sufficient to properly attenuate the unwanted spurious and bulk losses.

Depending on the severity, 40 to 50 dB of rejection for each of the high pass filters 416, 418 is adequate. Additionally, since the insertion loss of the upper passband 502 will be the sum of the two the high pass filters 416, 418 and the piezoelectric filter 420, low loss elements may be used to fabricate the high pass filters 416, 418.

In this embodiment, each of the low pass filters 422, 424 in the RF filter path 410 have a same low pass frequency response 604. It should be noted that, in different embodiments, the low pass frequency response 604 of each of the low pass filters 422, 424 may not be exactly the same and be somewhat misaligned. In this embodiment, the low pass frequency response 604 of each of the low pass filters 422, 424 has a low pass corner frequency flp that is at or below the lower notch edge at the frequency fnl of the notch 506. More specifically, the low pass corner frequency flp is also above the higher frequency fsu of the section 508. In this manner, the low pass frequency response 604 of the low pass filters 422, 424 pass portions of the RF signal 406 that are aligned with the section 508 of the lower passband 504. More specifically, the portion of the RF signal 406 that is below the low pass corner frequency flp is passed as the split RF signal 414. In this manner, the high pass filters 416, 418 reject the spurious modes and bulk losses that would degrade the section 508, but the portion of the RF signal 406 that is aligned by the section 508 in the lower passband 504 is passed through the RF filter path 410. For the low pass filters 422, 424, the low pass corner frequency flp is also below the lower notch edge at the frequency fnl and the rejection of the low pass filters 422, 424 at the lower notch edge at the frequency fnl is greater than the rejection of the notch 506. The exact amount of rejection of the low pass filters 422, 424 depends on many factors, including production margins, component tolerances, piezoelectric variations, and temperature.

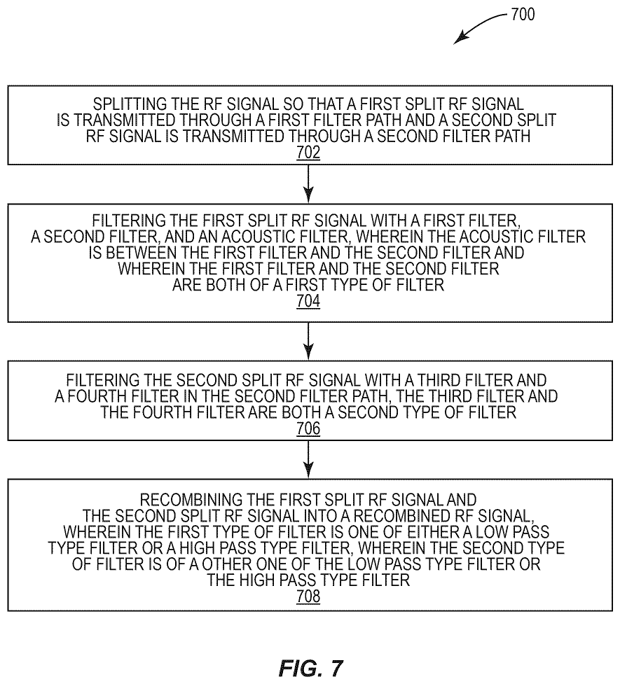

FIG. 7 illustrates a flow diagram 700 describing a method for filtering an RF signal, in accordance with some embodiments.

In some embodiments, the method of FIG. 7 is performed by the RF circuit 100 in FIG. 1 or the RF circuit 400 in FIG. 4. In some embodiments, the RF signal of FIG. 7 is the RF signal 106 in FIG. 1 or the RF signal 406 in FIG. 4. The flow diagram 700 includes blocks 702-708. Flow begins at block 702.

At block 702, the RF signal is split so that a first split RF signal is transmitted through a first filter path and a second split RF signal is transmitted through a second filter path. In some embodiments, the first split RF signal is the split RF signal 112 in FIG. 1 or the split RF signal 412 in FIG. 4. In some embodiments, the second split RF signal is the split RF signal 114 in FIG. 1 or the split RF signal 414 in FIG. 4. In some embodiments, the first filter path is the filter path 108 in FIG. 1 or the filter path 408 in FIG. 4. In some embodiments, the second filter path is the RF filter path 110 in FIG. 1 or the filter path 410 in FIG. 4. Flow then proceeds to block 704.

At block 704, the first split RF signal is filtered with a first filter, a second filter, and an piezoelectric filter, wherein the piezoelectric filter is between the first filter and the second filter and wherein the first filter and the second filter are both of a first type of filter. In some embodiments, the first filter is the low pass filter 116 in FIG. 1 or the high pass filter 416 in FIG. 4. In some embodiments, the second filter is the low pass filter 118 in FIG. 1 or the high pass filter 418 in FIG. 4. In some embodiments, the piezoelectric filter is the piezoelectric filter 120 in FIG. 1 or the piezoelectric filter 420 in FIG. 4. Flow then proceeds to block 706.

At block 706, the second split RF signal is filtered with a third filter and a fourth filter in the second filter path, the third filter and the fourth filter are both a second type of filter. In some embodiments, the third filter is the high pass filter 122 in FIG. 1 or the low pass filter 422 in FIG. 4. In some embodiments, the fourth filter is the high pass filter 124 in FIG. 1 or the low pass filter 424 in FIG. 4. Flow the proceeds to block 708.

At block 708, the first split RF signal and the second split RF signal are recombined into a recombined RF signal, wherein the first type of filter is one of either a low pass type filter or a high pass type filter and wherein the second type of filter is of another one of the low pass type filter or the high pass type filter. In FIG. 1, the split RF signal 112 and the split RF signal 114 are recombined into the RF signal 106 at the output terminal 104. In FIG. 1, the first type of filter is a low pass type filter and the second type of filter is a high pass type filter. In FIG. 4, the split RF signal 412 and the split RF signal 414 are recombined into the RF signal 406 at the output terminal 404. In FIG. 4, the first type of filter is a high pass type filter and the second type of filter is a low pass type filter.

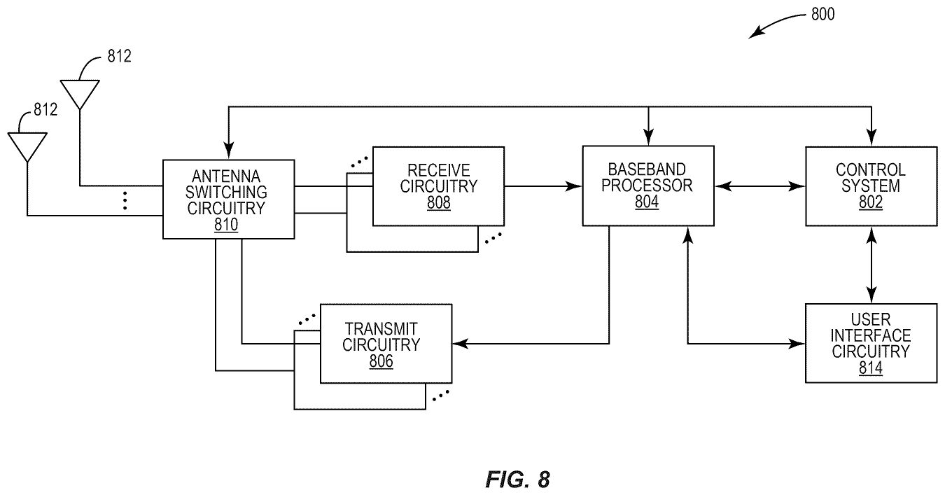

FIG. 8 illustrates a user element 800, in accordance with some embodiments.

With reference to FIG. 8, the concepts described above may be implemented in various types of user elements 800, such as mobile terminals, smart watches, tablets, computers, navigation devices, access points, and like wireless communication devices that support wireless communications, such as cellular, wireless local area network (WLAN), Bluetooth, and near field communications. The user element 800 will generally include a control system 802, a baseband processor 804, transmit circuitry 806, receive circuitry 808, antenna switching circuitry 810, multiple antennas 812, and user interface circuitry 814. In a non-limiting example, the control system 802 may be a field-programmable gate array (FPGA) or an application-specific integrated circuit (ASIC). In this regard, the control system 802 may include at least a microprocessor(s), an embedded memory circuit(s), and a communication bus interface(s). The receive circuitry 808 receives radio frequency signals via the antennas 812 and through the antenna switching circuitry 810 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC(s)).

The baseband processor 804 processes the digitized received signal to extract the information or data bits conveyed in the received signal. This processing typically comprises demodulation, decoding, and error correction operations, as will be discussed in greater detail below. The baseband processor 804 is generally implemented in one or more digital signal processors (DSPs) and ASICs.

For transmission, the baseband processor 804 receives digitized data, which may represent voice, data, or control information, from the control system 802, which it encodes for transmission. The encoded data is output to the transmit circuitry 806, where a digital-to-analog converter(s) (DAC(s)) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 812 through the antenna switching circuitry 810. The multiple antennas 812 and the replicated transmit and receive circuitries 806, 808 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the embodiments that follow.

Embodiments

What is claimed is:

1. A radio frequency (RF) circuit, comprising:
an input terminal;
an output terminal;
a first filter path connected between the input terminal and the output terminal, wherein the first filter path includes an piezoelectric filter, a first filter, and a second filter, wherein the piezoelectric filter is connected between the first filter and the second filter, wherein both the first filter and the second filter are of a first type of filter;
a second filter path connected between the input terminal and the output terminal, wherein the second filter path includes a third filter and a fourth filter, wherein both the third filter and the fourth filter are of a second type of filter;
wherein the first type of filter is one of either a low pass type filter or a high pass type filter; and
wherein the second type of filter is of another one of the low pass type filter or the high pass type filter.

2. The RF circuit of claim 1, wherein:
the first filter, the piezoelectric filter, and the second filter are cascaded in the first filter path; and
the third filter and the fourth filter are connected sequentially in the second filter path, wherein another piezoelectric filter is not included in the second filter path.

3. The RF circuit of claim 1, wherein:
the first type of filter is the low pass type filter and the second type of filter is the high pass type filter such that the first filter is a first low pass filter, the second filter is a second low pass filter, the third filter is a first high pass filter, and the fourth filter is a second high pass filter.

4. The RF circuit of claim 3, wherein:
the piezoelectric filter defines an upper passband, a lower passband, and a notch between the upper passband and the lower passband;
the upper passband defines a lower band edge;
the first low pass filter and the second low pass filter each have a low pass corner frequency that is at or is above a high notch edge of the notch; and
the first high pass filter and the second high pass filter each have a high pass corner frequency that is at or is above the high notch edge of the notch.

5. The RF circuit of claim 4, wherein:
the upper passband defines an upper band edge that is higher than the lower band edge of the upper passband;
the piezoelectric filter is configured to generate spurious modes above the lower band edge but below the upper band edge that degrade a section of the upper passband;
the low pass corner frequency of both the first low pass filter and the second low pass filter is below the section of the upper passband to filter out the spurious modes from the first filter path; and
the high pass corner frequency of both the first high pass filter and the second high pass filter is below the section of the upper passband to pass an RF signal in the section of the upper passband.

6. The RF circuit of claim 1, wherein:
the first type of filter is the high pass type filter and the second type of filter is the low pass type filter such that the first filter is a first high pass filter, the second filter is a second high pass filter, the third filter is a first low pass filter, and the fourth filter is a second low pass filter.

7. The RF circuit of claim 6, wherein:
the piezoelectric filter defines a lower passband, an upper passband, and a notch between the lower passband and the upper passband;
the lower passband defines an upper band edge;
the first high pass filter and the second high pass filter each have a high pass corner frequency that is at or is above the upper band edge of the lower passband; and
the first low pass filter and the second low pass filter each have a low pass corner frequency that is at or is above the upper band edge of the lower passband.

8. The RF circuit of claim 7, wherein:
the lower passband defines a lower band edge that is lower than the upper band edge;
the piezoelectric filter is configured to generate spurious modes below the upper band edge but above the lower band edge that degrade a section of the lower passband;
the high pass corner frequency of both the first high pass filter and the second high pass filter is above the section of the lower passband to filter out the spurious modes from the first filter path; and
the low pass corner frequency of both the first low pass filter and the second low pass filter is above the section of the lower passband to pass an RF signal in the section of the lower passband.

9. The RF circuit of claim 1, wherein the piezoelectric filter is a surface acoustic wave (SAW) filter or a bulk acoustic wave (BAW) filter.

10. The RF circuit of claim 1, wherein the RF circuit is formed in an integrated circuit (IC) package.

11. A method of filtering a radio frequency (RF) signal, comprising:
receiving the RF signal at an input terminal;
splitting the RF signal so that a first split RF signal is transmitted through a first filter path and a second split RF signal is transmitted through a second filter path;
filtering the first split RF signal with a first filter, a second filter, and an piezoelectric filter, wherein the piezoelectric filter is between the first filter and the second filter and wherein the first filter and the second filter are both of a first type of filter;
filtering the second split RF signal with a third filter and a fourth filter in the second filter path, the third filter and the fourth filter are both of a second type of filter;
recombining the first split RF signal and the second split RF signal into a recombined RF signal;
wherein the first type of filter is one of either a low pass type filter or a high pass type filter; and
wherein the second type of filter is of another one of the low pass type filter or the high pass type filter.

12. A user element comprising a radio frequency (RF) circuit, the RF circuit comprising:
an input terminal;
a first output terminal;
a first filter path connected between the input terminal and the first output terminal, the first filter path including an piezoelectric filter, a first filter, and a second filter, wherein the piezoelectric filter is connected between the first filter and the second filter, wherein both the first filter and the second filter are of a first type of filter;
a second filter path connected between the input terminal and the first output terminal, wherein the second filter path includes a third filter and a fourth filter, wherein both the third filter and the fourth filter are of a second type of filter;
wherein the first type of filter is one of either a low pass type filter or a high pass type filter; and
wherein the second type of filter is of another one of the low pass type filter or the high pass type filter.

13. The user element of claim 12, wherein:
the first filter, the piezoelectric filter, and the second filter are cascaded in the first filter path; and
the third filter and the fourth filter are connected sequentially in the second filter path, wherein another piezoelectric filter is not included in the second filter path.

14. The user element of claim 13, wherein:
the first type of filter is the low pass type filter and the second type of filter is the high pass type filter such that the first filter is a first low pass filter, the second filter is a second low pass filter, the third filter is a first high pass filter, and the fourth filter is a second high pass filter.

15. The user element of claim 14, wherein:
the piezoelectric filter defines an upper passband, a lower passband, and a notch between the upper passband and the lower passband;
the upper passband defines a lower band edge;
the first low pass filter and the second low pass filter each have a low pass corner frequency that is at or is above the lower band edge of the upper passband; and
the first high pass filter and the second high pass filter each have a high pass corner frequency that is at or is above the lower band edge of the upper passband.

16. The user element of claim 15, wherein:
the upper passband defines an upper band edge that is higher than the lower band edge;
the piezoelectric filter is configured to generate spurious modes above the lower band edge but below the upper band edge that degrade a section of the upper passband;
the low pass corner frequency of both the first low pass filter and the second low pass filter is below the section of the upper passband to filter out the spurious modes from the first filter path; and
the high pass corner frequency of both the first high pass filter and the second high pass filter is below the section of the upper passband to pass an RF signal in the section of the upper passband.

17. The user element of claim 12, wherein:
the first type of filter is the high pass type filter and the second type of filter is the low pass type filter such that the first filter is a first high pass filter, the second filter is a second high pass filter, the third filter is a first low pass filter, and the fourth filter is a second low pass filter.

18. The user element of claim 17, wherein:
the piezoelectric filter defines a lower passband, an upper passband, and a notch between the lower passband and the upper passband;
the lower passband defines an upper band edge;
the first high pass filter and the second high pass filter each have a high pass corner frequency that is at or is below the upper band edge of the lower passband; and
the first low pass filter and the second low pass filter each have a low pass corner frequency that is at or is below the upper band edge of the lower passband.

19. The user element of claim 18, wherein:
the lower passband defines a lower band edge that is lower than the upper band edge;
the piezoelectric filter is configured to generate spurious modes below the upper band edge but above the lower band edge that degrade a section of the lower passband;
the high pass corner frequency of both the first high pass filter and the second high pass filter is above the section of the lower passband to filter out the spurious modes from the first filter path; and
the low pass corner frequency of both the first low pass filter and the second low pass filter is above the section of the lower passband to pass an RF signal in the section of the lower passband.

20. The user element of claim 12, wherein the piezoelectric filter is a surface acoustic wave (SAW) filter or a bulk acoustic wave (BAW) filter.
